(19) United States
(12) Patent Application Publication
(10) Pub. No.: US 2026/0150705 A1
(43) Pub. Date: May 28, 2026

(54) METHODS FOR FORMING ALIGNMENT MARKS

(71) Applicant: Taiwan Semiconductor Manufacturing Company, LTD., Hsinchu (TW)

(72) Inventors: Tzu Jung Tien, Hsinchu (TW); Jen-Yuan Chang, Hsinchu (TW)

(21) Appl. No.: 18/961,641

(22) Filed: Nov. 27, 2024

(51) Int. Cl. H01L 21/48; H01L 23/498; H01L 23/544

(52) U.S. Cl. CPC H10W 70/095; H10W 46/00; H10W 70/635; H10W 46/301

(57) ABSTRACT

Alignment marks on an interposer are formed within a chip area instead of in a wafer scribe line or die street. A through-substrate via (TSV) trench and at least one alignment mark trench are formed in a chip area of a substrate. The TSV trench and the at least one alignment mark trench are filled with a metal to form a filled TSV trench and the at least one alignment mark. The thickness of the substrate is reduced to form a through-substrate via (TSV) from the filled TSV trench. This reduces process defects during dicing and improves yield.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a plan view of one embodiment of a wafer substrate having interposers that include through-substrate vias (TSVs) and alignment marks on the chip boundary.

FIG. 1B is a cross-sectional view of the wafer substrate.

FIG. 2 is a flow chart illustrating a first method for forming the TSVs and alignment marks on a wafer substrate, in accordance with some embodiments.

FIG. 3 is a cross-sectional view of the substrate after a photoresist layer has been applied and patterned.

FIG. 4 is a cross-sectional view of the substrate after etching to form a TSV trench and an alignment mark trench.

FIG. 5 is a flow chart illustrating a second method for forming the TSVs and alignment marks on a wafer substrate, in accordance with some embodiments.

FIG. 6 is a cross-sectional view of the substrate after a photoresist layer has been applied and patterned to form the alignment mark trench.

FIG. 7 is a cross-sectional view of the substrate after etching to form the alignment mark trench.

FIG. 8 is a cross-sectional view of the substrate after the photoresist layer has been removed.

FIG. 9 is a cross-sectional view of the substrate after a photoresist layer has been applied and patterned to form the TSV trench.

FIG. 10 is a cross-sectional view of the substrate after etching to form the alignment mark trench.

FIG. 11 is a cross-sectional view of the substrate after the photoresist layer has been removed, showing the substrate with a TSV trench and an alignment mark trench.

FIG. 12 is a flow chart showing further method steps for forming the interposer, in accordance with some embodiments.

FIG. 13 is a cross-sectional view of the substrate after filling the trenches with a metal to obtain a filled TSV trench and an alignment mark.

FIG. 14 is a cross-sectional view of the substrate after forming a redistribution layer (RDL) upon the front surface of the substrate.

FIG. 15 is a cross-sectional view of the substrate showing two chip areas separated by a scribe line.

FIG. 16 is a cross-sectional view of the substrate after chips are bonded to the two chip areas.

FIG. 17 is a cross-sectional view of the substrate after underfill is applied.

FIG. 18 is a cross-sectional view of the substrate after encapsulant is applied.

FIG. 19 is a cross-sectional view of the substrate after the back side has been reduced in thickness to form through-substrate vias (TSVs).

FIG. 20 is a cross-sectional view of the substrate showing the addition of bumps and identifying a wafer scribe line where dicing will be performed.

FIG. 21 is a cross-sectional view showing a semiconductor package formed from an interposer with chips stacked thereon.

FIG. 22A is a plan view showing two dies stacked upon each other, using alignment marks in each die to verify their placement. FIG. 22B is a cross-sectional view.

FIG. 23 is a cross-sectional view showing a Chip-on-Wafer-on-Substrate structure.

FIGS. 24A-24I illustrate different embodiments of the alignment mark.

FIG. 25 is an illustration showing various aspects of the TSV and the alignment mark.

FIG. 26A and FIG. 26B are plan views showing interposers with different numbers of alignment marks.

FIG. 27A and FIG. 27B are plan views showing two different mask designs for making interposers with different numbers of alignment marks.

FIGS. 28A-28C are different views of a structure suitable for silicon photonics.

FIG. 28A is a plan view of the structure. FIG. 28B is a cross-sectional view along line B-B of FIG. 28A. FIG. 28C is a cross-sectional view along line C-C of FIG. 28A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

It is noted that as used herein, the term “trench” is used to refer to a volume which may be empty or may be filled, and which should be clear from the context of the discussion.

The present disclosure relates to interposer structures for chip alignment and test line design. Alignment marks are commonly made in the wafer scribe line, which separates individual dies or chips from each other on the wafer substrate. They can also be used as test line structures for wafer acceptance testing. Such alignment marks are commonly made of a metal, such as copper. However, when using a dicing saw, the copper of such structures in the wafer scribe line can remain upon the dicing saw, which can cause passivation and affect the profile of the cut die(s). In severe cases, die cracks can occur, resulting in scrap. In the present disclosure, the alignment marks are moved out of the wafer scribe line and into the chip area of the wafer substrate, avoiding such issues.

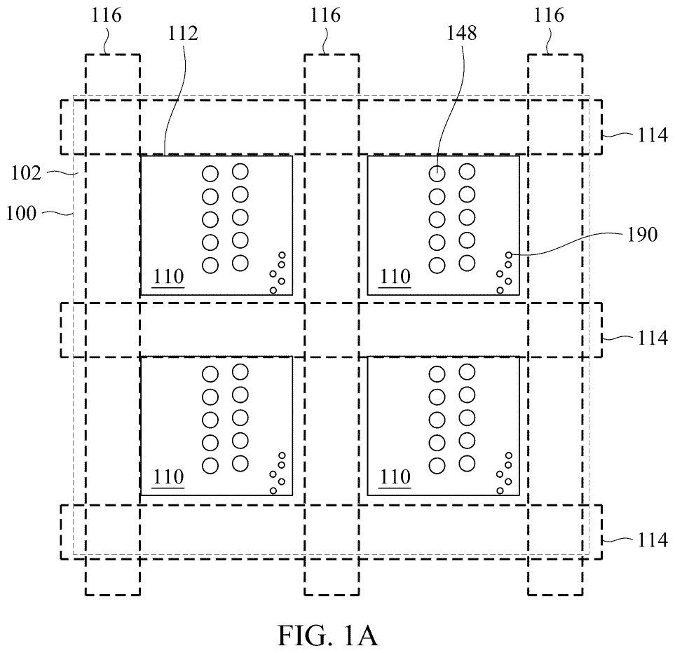

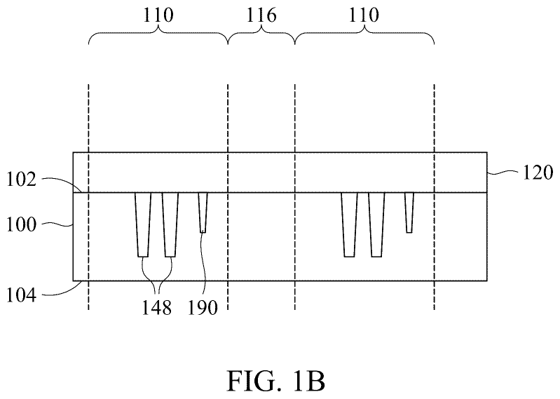

FIG. 1A and FIG. 1B provide different views of an interposer wafer substrate upon which multiple unfinished interposers 110 are illustrated. FIG. 1A is a plan view, and FIG. 1B is a cross-sectional view.

Referring first to FIG. 1A, the front side or upper surface 102 of the substrate 100 is shown in dashed lines. Four unfinished interposers 110 are shown. Each interposer 110 includes a set of filled through-substrate via (TSV) trenches 148, drawn in two columns of five trenches. Each interposer also includes at least one alignment mark 190. Here, five alignment marks 190 are shown in the bottom right corner of each unfinished interposer 110. Each interposer is formed within a chip area 112 on the substrate. Also illustrated are three horizontal wafer scribe lines 114 and three vertical wafer scribe lines 116 which separate each chip area 112 from other chip areas.

Referring now to FIG. 1B, the filled TSV trenches 148 and the alignment mark 190 extend from the upper surface 102 into the substrate 100, but do not yet reach the back side or bottom surface 104 of the substrate. A redistribution layer (RDL) 120 is formed over the upper surface 102 of the substrate. The RDL includes one or more layers of electrical interconnects that permit components to communicate with each other. The electrical interconnects are separated by a dielectric material. The RDL may be formed by several repeated steps of applying and patterning a dielectric layer, then applying and patterning a layer of electrically conductive materials. One vertical wafer scribe line 116 is indicated between two unfinished interposers 110.

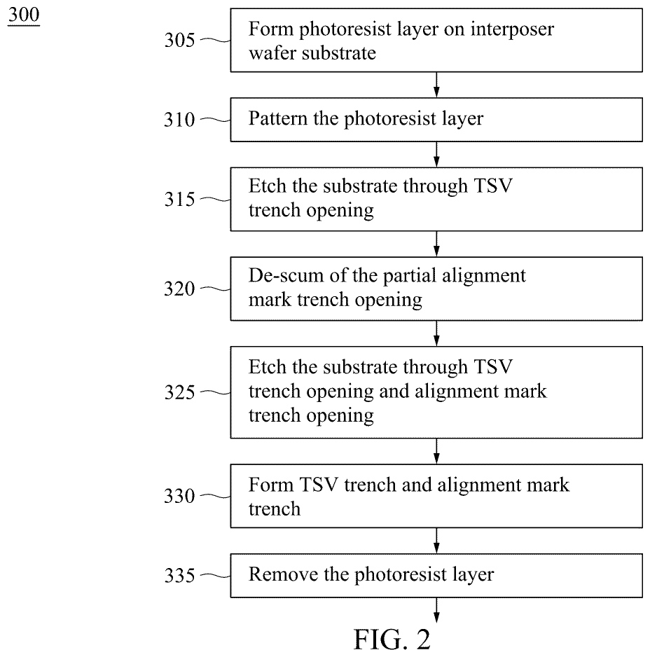

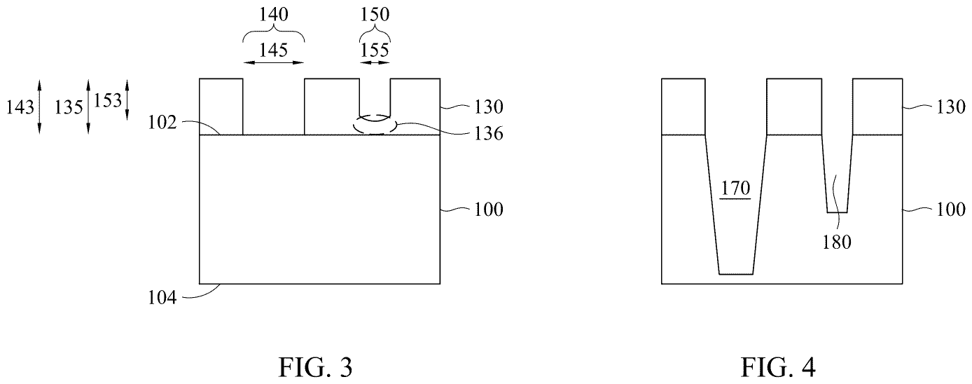

FIG. 2 is a flow chart illustrating a first method 300 for forming the TSVs and alignment marks on a wafer substrate, in accordance with some embodiments. FIG. 3 and FIG. 4 illustrate various steps of the method. These figures provide different views for better understanding. While the method steps are discussed below in terms of forming one TSV and one alignment mark in one chip area on an interposer wafer substrate, such discussion should also be broadly construed as applying to concurrent formation of multiple TSVs and/or multiple alignment marks in several chip areas upon the substrate. It is noted that not all steps described in the flow chart are required, and not all method steps are described in the flow chart.

Initially, FIG. 3 shows the interposer wafer substrate from which interposers will be formed. The substrate 100 has a first or front side 102 and a second or back side 104. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

In step 305 of FIG. 2, and referring to FIG. 3, a photoresist layer 130 is formed upon the upper surface 102 of the substrate. The photoresist layer has a height 135. In step 310, the photoresist layer is patterned. As illustrated in FIG. 3, the photoresist layer includes a TSV trench opening 140 on the left side and includes a partial alignment mark trench opening 150 on the right side. The upper surface 102 is exposed in the TSV trench opening 140. Put another way, the TSV trench opening 140 has a depth 143 which is equal to the photoresist layer height 135. In contrast, in the partial alignment mark trench opening 150, photoresist 136 is still present at the bottom. The term “partial” is used here to indicate the upper surface 102 is not exposed. Put another way, the partial alignment mark trench opening 150 has a depth 153 which is less than the photoresist layer height 135. The photoresist at the bottom of the partial alignment mark trench opening 150 may be “resist scum” which is not developed. This may occur, for example, when, as illustrated here, the TSV trench opening 140 has a diameter 145 which is greater than the diameter 155 of the partial alignment mark trench opening 150.

In step 315 of FIG. 2, and as illustrated in FIG. 4, the substrate is etched through the patterned photoresist layer 130. This may be done by dry etch or wet etch, and typically a plasma etch is performed. The TSV trench opening 140 and the partial alignment mark trench opening 150 are both exposed to the etchant. However, due to the presence of the photoresist 136, only the TSV trench opening is etched. Then, at step 320 of FIG. 2, a de-scumming process is performed to remove the photoresist 136 in the partial alignment mark trench opening and obtain an alignment mark trench opening 158. This may be done, for example, using an oxygen plasma. Then, in step 325 of FIG. 2, the substrate is etched again through the patterned photoresist layer 130. The substrate is now exposed through both openings. As a result and as indicated in step 330, a TSV trench 170 and an alignment mark trench 180 are thus formed in the substrate. Due to the presence of photoresist 136 in the partial alignment mark trench opening 150 and the consequent shorter etching time, the resulting depth 183 of the alignment mark trench 180 is less than the depth 173 of the TSV trench 170. In step 335, the patterned photoresist layer 130 is removed.

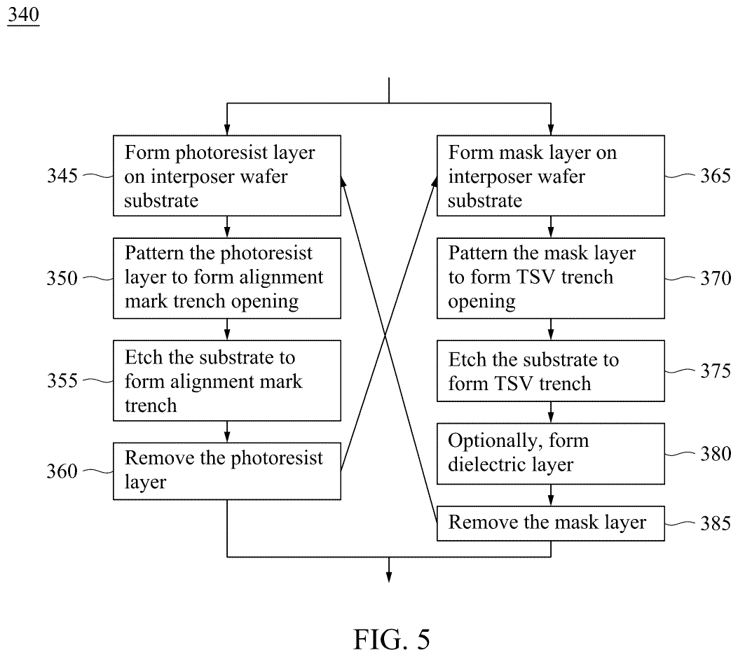

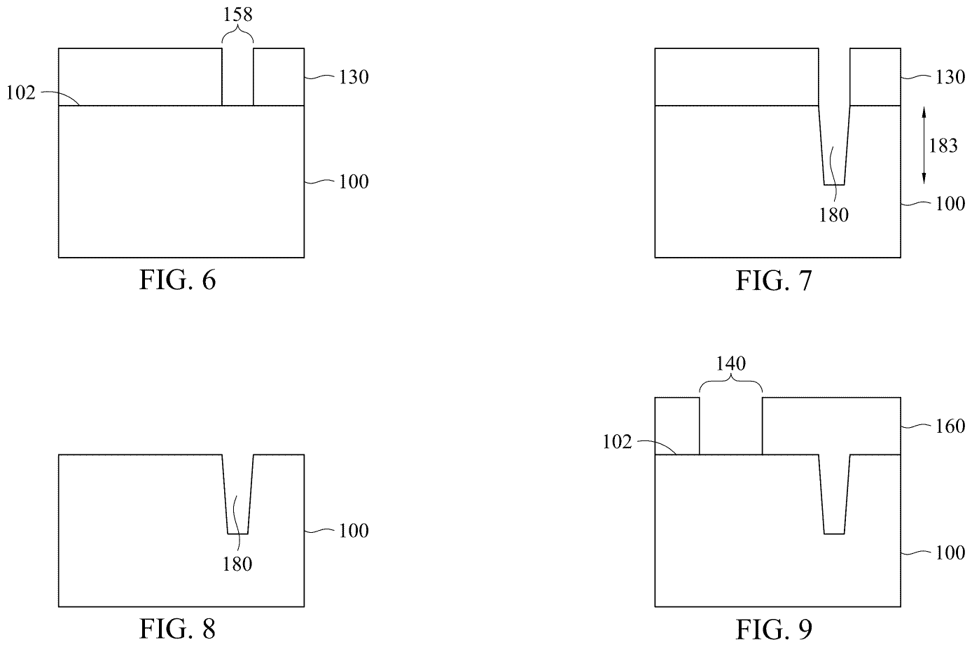

FIG. 5 is a flow chart illustrating a second method 340 for forming the TSVs and alignment marks on a wafer substrate, in accordance with some embodiments. FIGS. 6-11 illustrate various steps of the method. These figures provide different views for better understanding. Again, while the method steps are discussed below in terms of forming one TSV and one alignment mark in one chip area on an interposer wafer substrate, such discussion should also be broadly construed as applying to concurrent formation of multiple TSVs and/or multiple alignment marks in several chip areas upon the substrate. Again, not all steps described in the flow chart are required, and not all method steps are described in the flow chart.

In step 345 of FIG. 5, and referring to FIG. 6, a photoresist layer 130 is formed upon the upper surface 102 of the substrate. In step 350, the photoresist layer is patterned to form an alignment mark trench opening 158. The upper surface 102 is exposed in the alignment mark trench opening 158.

Next, in step 355 of FIG. 5, and referring to FIG. 7, the substrate is etched through the patterned photoresist layer 130 to form an alignment mark trench 180. The depth 183 of the alignment mark trench 180 may be controlled, for example, by the etching time. At this point, the alignment mark trench is empty. Then, in step 360 of FIG. 5, and as shown in FIG. 8, the photoresist layer 130 is removed.

In step 365 of FIG. 5, and referring to FIG. 9, a mask layer 160 is formed upon the upper surface 102 of the substrate. Depending on whether a dielectric layer is desired to be formed between the substrate and the resulting through-substrate via (TSV), the mask layer may be a second photoresist layer, or may be a hard mask made of a material such as amorphous carbon, SiN, SiON, TiN, etc. In step 370, the mask layer is patterned to form a TSV trench opening 140. Again, the upper surface 102 is exposed in the TSV trench opening 140.

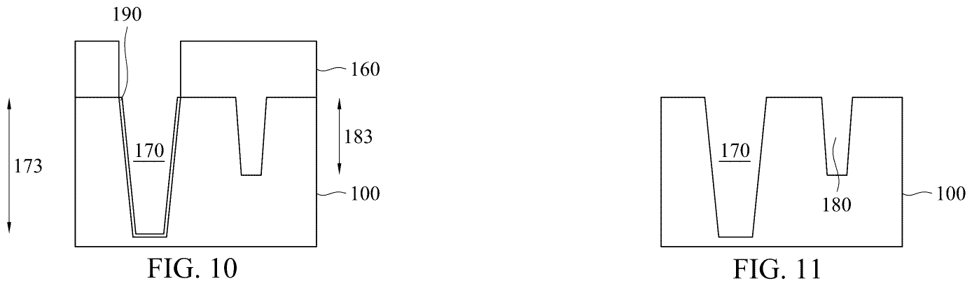

Next, in step 375 of FIG. 5, and referring to FIG. 10, the substrate is etched through the patterned mask layer 160 to form a TSV trench 170. The depth 173 of the TSV trench 170 is greater than the depth 183 of the alignment mark trench. This may be done, for example, by etching the substrate for a longer time period than was used in step 355. At this point, the TSV trench is empty. In optional step 380 of FIG. 5, a dielectric layer 190 may be formed upon the surface of the TSV trench 170 if desired. This may be done, for example, by thermal oxidation (where exposed surfaces are heated in the presence of oxygen or steam) or by atomic layer deposition (ALD). If this optional step is performed, the mask layer 160 is usually a hard mask rather than photoresist. The dielectric layer 190 is shown in FIG. 10, but will not be further illustrated.

Then, in step 385 of FIG. 5, and as shown in FIG. 11, the patterned mask layer 160 is removed. The resulting structure is the same as that of FIG. 4 after the photoresist layer has been removed. It is noted that the alignment mark trench 180 and the TSV trench 170 can be formed in either order.

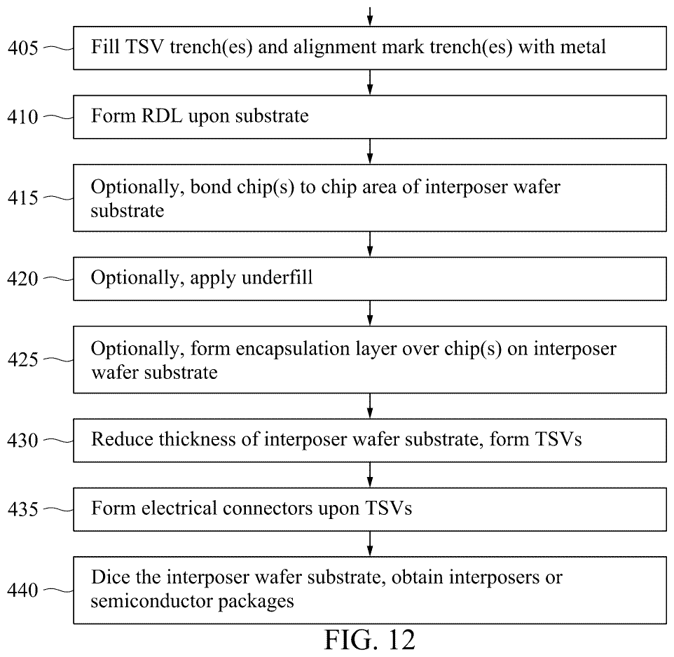

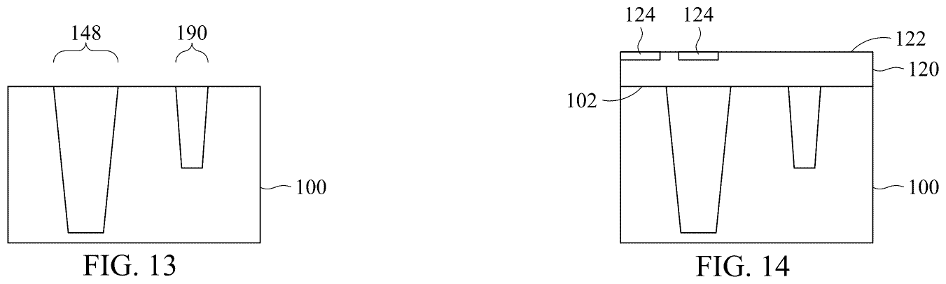

FIG. 12 is a flow chart showing further method steps for forming a semiconductor package 230 containing the interposer 110, in accordance with some embodiments. FIGS. 13-21 illustrate various steps of the method. These figures provide different views for better understanding. Again, while the method steps are discussed below in terms of forming one TSV and one alignment mark in one chip area on an interposer wafer substrate, such discussion should also be broadly construed as applying to concurrent formation of multiple TSVs and/or multiple alignment marks in several chip areas upon the substrate. Again, not all steps described in the flow chart are required, and not all method steps are described in the flow chart.

In step 405 of FIG. 12, and referring to FIG. 13, the TSV trench and the alignment mark trench are filled with an electrically conductive material, such as a metal. In particular embodiments, copper is used as the material. As a result, a filled TSV trench 148 and an alignment mark 190 are formed in the substrate 100.

Then, in step 410 of FIG. 12, and referring to FIG. 14, a redistribution layer (RDL) 120 is formed upon the front side 102 of the substrate 100. The RDL includes a dielectric material and electrically conductive components within the dielectric material. The RDL may be formed from several different steps that form several smaller layers that together form the RDL. Generally speaking, any electrical routing with any desired paths and made up of any desired components is contemplated. In particular, bond pads 124 are illustrated on the surface 122 of the RDL.

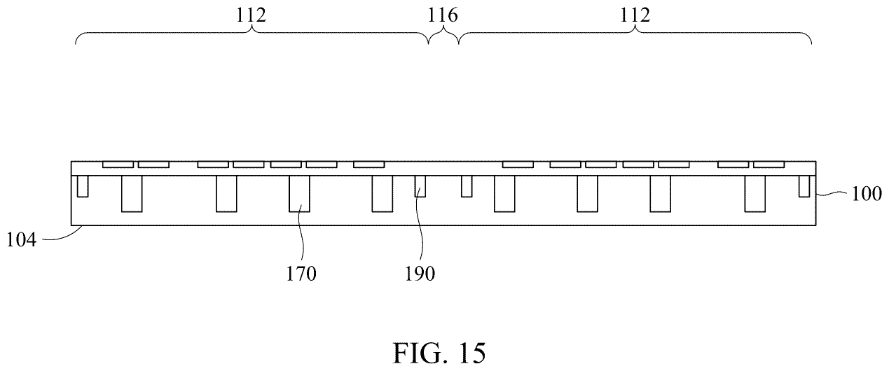

Referring now to FIG. 15, a larger cross-section of the wafer substrate 100 is shown. Two chip areas 112 are indicated, with a vertical wafer scribe line 116 between them. As seen here, the TSV trenches 170 and alignment marks 190 do not extend to the back side 104 of the wafer substrate. It should also be noted that no metal is present in the RDL above the alignment marks 190.

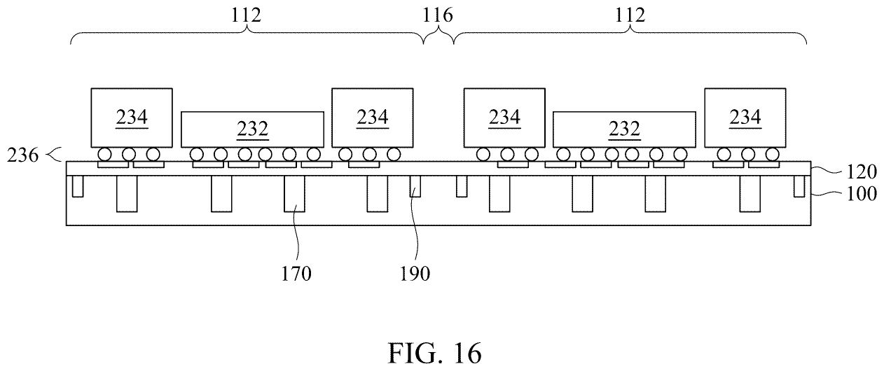

Continuing, in step 415 of FIG. 12, and referring to FIG. 16, one or more chips are bonded to the interposer wafer substrate 100, and in particular within a chip area 112. Two different chips are illustrated here, for example a System-on-Chip (SOC) 232 and memory chips 234. On an SoC, many electronic components are combined together on one common substrate. The SoC contains a semiconductor die, and is shown here as being located between two memory chips. The SoC may contain, for example, a central processing unit (CPU) or a graphics processing unit (GPU). The memory chips may be, for example, high bandwidth memory (HBM). Other electronic components may also be present. Generally, any number of dies/chips may be bonded/attached. The bonding may be performed, for example, through an interconnect layer 236 containing electrical contacts such as lands, balls, pins, bumps, pillars, or other similar structures on each chip, to the bond pads 124 in the RDL 120 upon the wafer substrate.

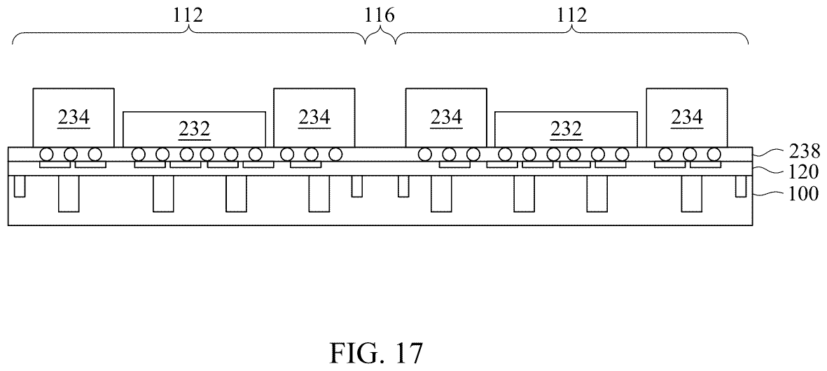

Subsequently, in step 420 of FIG. 12, and referring to FIG. 17, an underfill material 238 is applied to the wafer substrate 100. This may be done, for example, using a capillary flow process or other suitable method. This fills any gaps between the chips 232, 234 and the interposer wafer substrate 100. A curing process may then be performed to cure the underfill.

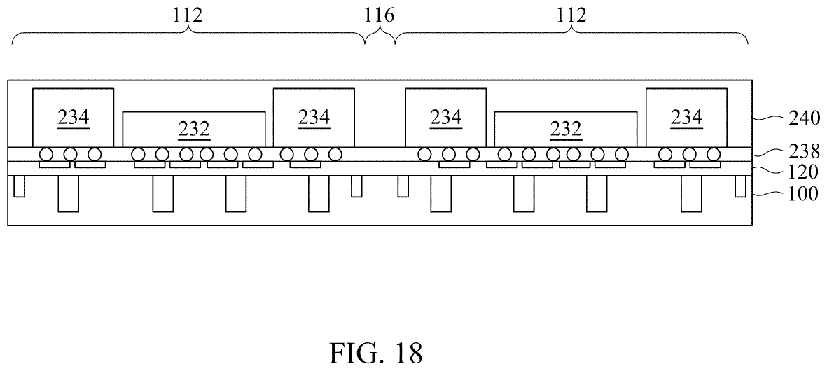

Then, in step 425 of FIG. 12, and referring to FIG. 18, an encapsulant is applied to cover the chips 232, 234. The encapsulant may be applied using suitable methods and materials. The encapsulant may then be cured to form an encapsulation layer 240.

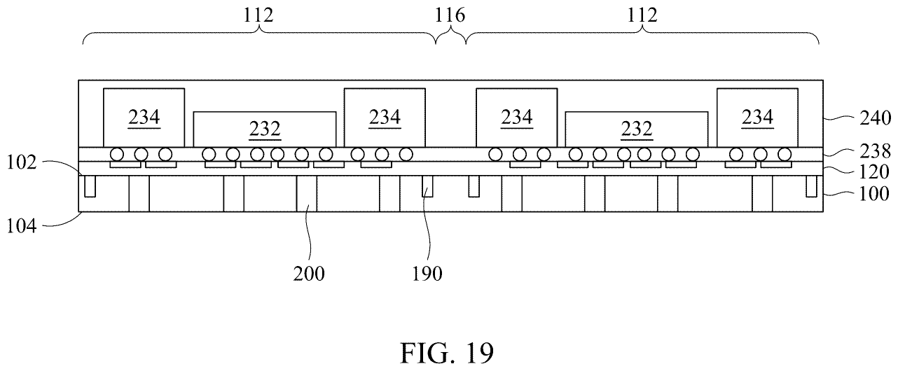

Continuing, in step 430 of FIG. 12, and referring to FIG. 19, the thickness of the interposer wafer substrate 100 is reduced to expose the TSV trench(es). This may be done, for example, by grinding the back side 104 of the substrate. As a result, through-substrate vias (TSVs) 200 are formed that extend through the substrate between the front side 102 and the back side 104. It is noted that the alignment marks 190 are not exposed upon the back side 104 of the substrate.

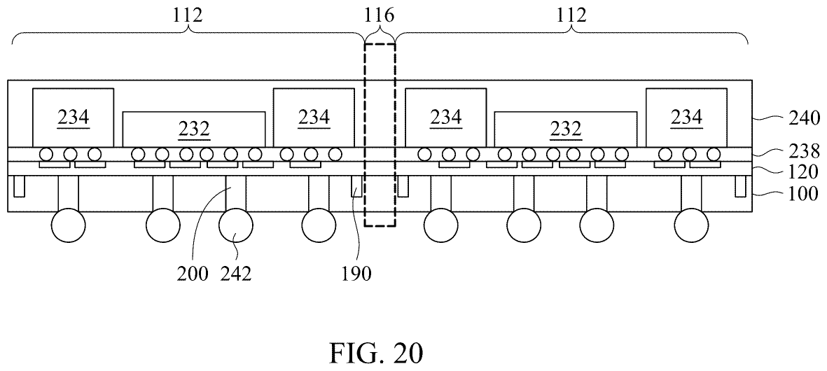

Next, in step 435 of FIG. 12, and referring to FIG. 20, electrical connectors 242 are formed upon the TSVs 200. These may be, for example, lands, balls, pins, bumps, pillars, or other similar structures. Finally, in step 440 of FIG. 12, the interposer substrate 100 is diced along the wafer scribe line.

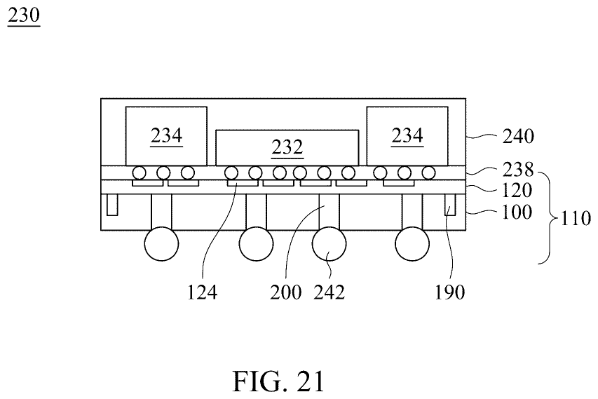

FIG. 21 shows the resulting semiconductor package 230. The interposer 110 includes the substrate 100 having TSVs 200 and alignment marks 190 therein, the RDL 120, and the electrical connectors 242. The interposer 110 can be described as having conductive features (e.g., pads 124 and electrical connectors 242) on opposite sides. Conductive traces and vias are formed in the interposer to electrically interconnect those conductive features. The interposer wafer substrate does not include active devices such as transistors and diodes, and may or may not include passive devices such as capacitors, resistors, or inductors. The chips 232, 234, underfill 238, and the encapsulation layer 240 are mounted upon the interposer. The package 230 can then be bonded to package substrates or printed circuit boards.

Alternatively, steps 405, 410, 430, 435, and 440 can be performed to obtain the interposer 110 by itself without chips 232, 234 thereon.

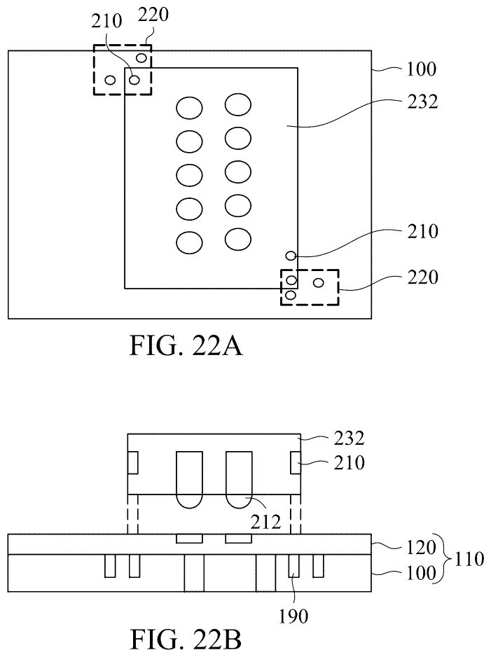

FIG. 22A and FIG. 22B show one usage of the alignment marks. FIG. 22A is a plan view, and FIG. 22B is a cross-sectional view. A chip 232 is shown upon an interposer 110 having a substrate 100 and an RDL 120. The chip 232 has alignment marks 210, as does the interposer. As illustrated here, on the interposer, patterns 220 formed from a plurality of alignment marks are shown at opposite corners. As illustrated here, they provide both longitudinal and horizontal alignment. Alignment marks 210 on the chip correspond to alignment marks 190 on the interposer, and are used to align the connectors 212 on the chip with the bond pads 124 on the interposer. They may be overlapping, non-overlapping, or partially-overlapping alignment marks as desired. It is noted that the alignment marks may be visible at different wavelengths, and wavelengths in the visible spectrum do not have to be used during the alignment process. The chip may be placed upon the interposer using pick-and-place methods. Alignment measurements can be made after pick-and-place.

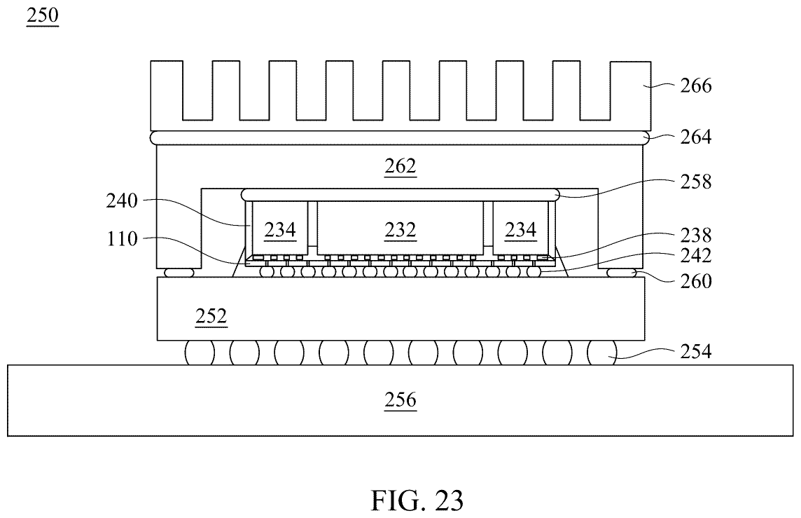

FIG. 23 is a cross-sectional view showing a Chip-on-Wafer-on-Substrate structure 250. The package 230 of FIG. 21 includes the chips 232, 234, underfill 238, and encapsulation layer 240 which are mounted upon an interposer 110 having electrical connectors 242. The interposer 110 is then bonded to the top surface of a substrate 252 to obtain the Chip-on-Wafer-on-Substrate structure. The backside of the substrate also includes an interconnect layer 254 which will be used to join the Chip-on-Wafer-on-Substrate structure to a motherboard 256 (for example).

Continuing, a thermal interface material (TIM) is deposited over the semiconductor package 230 to improve thermal coupling. This is referred to herein as an inner TIM layer 258. Suitable TIMs may include polymers, which may contain thermally conductive fillers therein. Some non-limiting examples of thermally conductive fillers may include aluminum oxide, boron nitride, aluminum nitride, aluminum, copper, silver, and indium. The TIM may be a film or a sheet, including for example carbon nanotubes (CNTs) or graphite. The TIM may be in the form of a solid pad, paste, gel, grease, or a phase change material, among others. The TIM may be applied continuously over the package. Sometimes, voids or air gaps may be present within the TIM layer, for example to reduce lateral thermal interaction. In some embodiments, the thickness of the TIM layer may range from 100 micrometers (μm) to about 3 millimeters (mm), although other ranges are within the scope of the present disclosure.

An adhesive 260 is also disposed upon the substrate 252 and around the package 230. The adhesive 260 may be, for example, an epoxy, or a silicon resin, a glue, or other adhesive suitable for use with semiconductor devices.

A lid 262 is attached to the substrate 252 and over the semiconductor package. The lid both physically protects the package, and also acts as a heat spreader that dissipates heat over the greater surface area of the lid. The lid is usually made from a material with high thermal conductivity, such as aluminum, steel, stainless steel, copper, and other similar materials. The lid 262 is affixed to the substrate by the adhesive 260. The adhesive and the TIM may need to be cured by applying heat at a suitable temperature for a suitable time period.

A second TIM layer 264 is placed upon the lid 262, which thermally couples the lid to the heat sink 266. This layer may have the same composition and form as described for the inner TIM layer 258. The heat sink may be made of materials such as aluminum or copper. The heat sink may include fins to increase surface area.

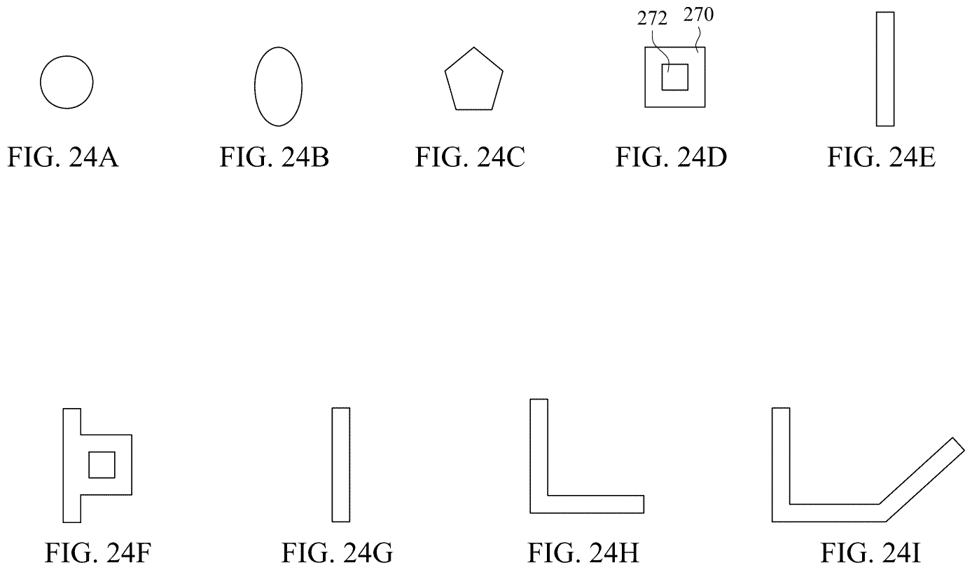

FIGS. 24A-24I are plan views illustrating different possible shapes for the alignment mark 190 and/or the through-substrate via (TSV) 200. These plan views are considered at the upper surface 102 of the substrate, and it should be recognized that these shapes may change through the depth of the substrate due to variations in the etching process. Each shape may be described as a combination of points and/or lines.

FIG. 24A illustrates a circular shape formed from the electrically conductive material. FIG. 24B illustrates an elliptical shape. FIG. 24C illustrates a polygonal shape. While a pentagonal shape is illustrated, other polygonal shapes such as triangular, square, rectangular, hexagonal, etc. are also contemplated. FIG. 24D illustrates a ring or annular shape. In this shape, the perimeter 270 is formed from the electrically conductive material deposited in step 405 of FIG. 5. The center 272 is formed from the substrate. This may also be any shape such as triangular, square, rectangular, hexagonal, etc. FIG. 24E illustrates a linear or rectangular shape. It is generally contemplated that any combination of these shapes may also be used as an alignment mark. For examples, FIG. 24F illustrates a combination of a linear shape and a ring shape.

The alignment mark(s) may extend in one or multiple directions. FIG. 24G illustrates a linear alignment mark that extends in one direction. FIG. 24H illustrates an alignment mark formed from two lines that extend in different directions. FIG. 24I illustrates an alignment mark formed from three lines, which extend in three different directions (e.g. longitudinal, transverse, and diagonal).

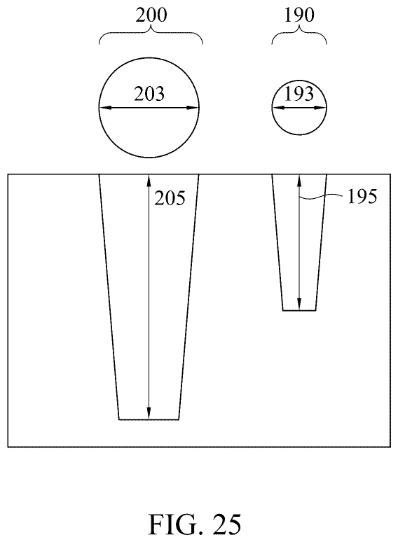

FIG. 25 is an illustration showing various aspects of the TSV 200 and the alignment mark 190. Both a plan view and a cross-sectional view are provided.

As indicated in the plan view of FIG. 25, the TSV has a diameter 203, and the alignment mark also has a diameter 193. The term “diameter” is used here to refer to the longest value between opposite corners or sides of the TSV and/or the alignment mark 190 (which will depend on the shape, as illustrated in FIGS. 24A-24I). Generally, the diameter 203 of the TSV is greater than the diameter 193 of the alignment mark. More particularly, in some specific embodiments, the TSV diameter 203 is at least three times greater than the alignment mark diameter 193, and may be up to ten times greater. Other ranges and values are also contemplated. However, in some embodiments, the diameter 203 of the TSV has the same value as the diameter 193 of the alignment mark. In other embodiments, the diameter 203 of the TSV is less than the diameter 193 of the alignment mark.

Referring to the cross-sectional view of FIG. 25, the TSV height or depth 205 is greater than the alignment mark height or depth 195. More particularly, in some specific embodiments, the TSV height 205 is at least two times greater than the alignment mark diameter 195, and may be up to ten times greater. Other ranges and values are also contemplated. As a result, the alignment mark does not show, or is not exposed, on the back side of the final interposer, and an electrical connector will not be applied thereon.

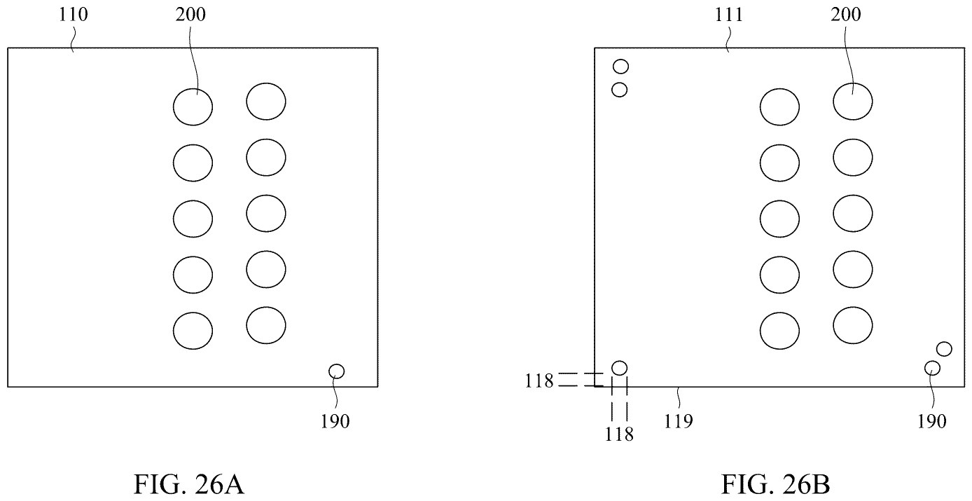

FIG. 26A and FIG. 26B are plan views showing interposers with different numbers of alignment marks at various locations. In the interposer 110 of FIG. 26A, one alignment mark 190 is illustrated at the bottom right corner. In the interposer 110 of FIG. 26B, six alignment marks 190 are illustrated. Two alignment marks are present at each of the top left corner and the bottom right corner. One alignment mark is present at the bottom left corner, and one alignment is present at the middle of the right side. The patterns of these two interposers can both be used to positively identify a specific orientation for the interposer. Generally, the alignment mark(s) 190 are placed at a distance 118 that is more than 1 micrometer from any edge 119 of the interposer/chip area. TSVs 200 are also visible.

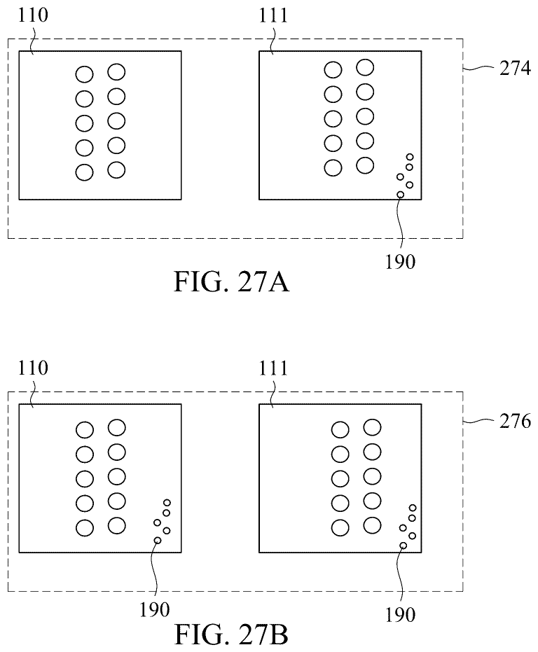

FIG. 27A and FIG. 27B are plan views showing two different mask designs for making interposers with different numbers of alignment marks. Each mask design 274, 276 is identified by dashed lines, and makes two interposers at a time. In the mask design 274 of FIG. 27A, one interposer 110 will have zero alignment marks and one interposer 111 will have five alignment marks 190 at the bottom right corner. In the mask design 276 of FIG. 27B, both interposers 110, 111 will have five alignment marks 190 at the bottom right corner.

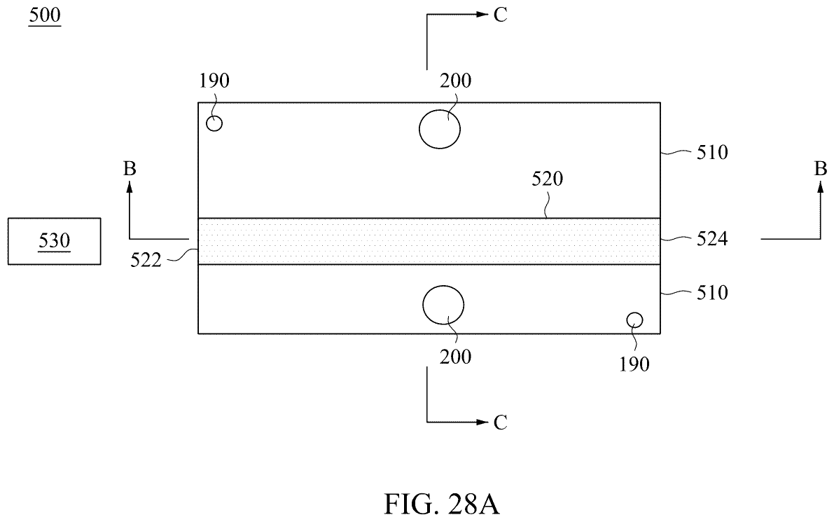

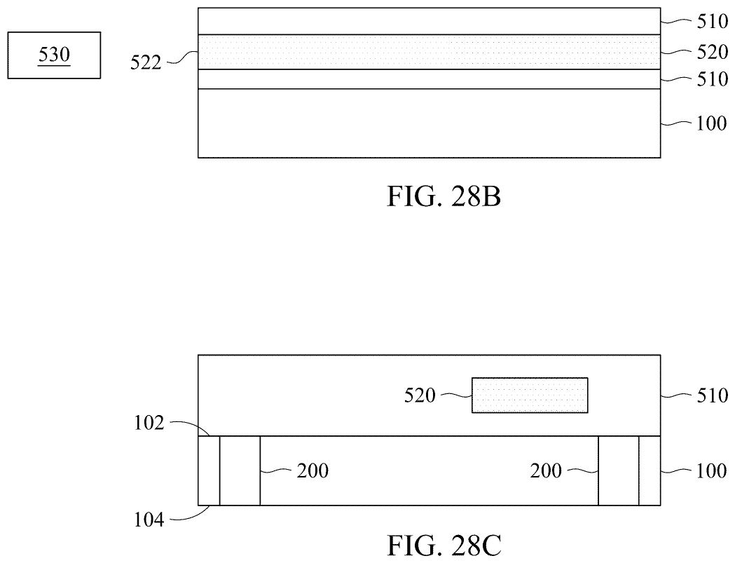

It is noted that these structures may also be useful in silicon photonics structures, where a filled TSV trench may act as a bond pad. FIGS. 28A-28C are different views of such a structure 500. In silicon photonics, a waveguide is commonly formed from a core surrounded by a cladding, with the refractive index of the core being greater than the refractive index of the cladding. Thus, the cladding encourages total internal reflection within the waveguide. The waveguide may be made, for example, of silicon nitride (Si₃N₄) or silicon. The cladding may be made, for example of silicon dioxide (SiO₂). For reference, silicon has a refractive index of about 3.6, silicon nitride has a refractive index of about 1.98, and silicon dioxide has a refractive index of about 1.45. Here, the structure includes a substrate 100 (e.g. silicon). A cladding layer 510 is present upon a front side 102 of the substrate 100, and a waveguide 520 is present within the cladding. Alignment marks 190 are also present on the front side 102 of the substrate, and TSVs 200 extend through the substrate. There is no metal located above them in the cladding layer. A light source 530 (such as a laser) may be connected to an input end 522 of the waveguide, and an output end 524 is at the opposite end of the waveguide. Alternatively, the cladding layer may be placed on the back side 104 of the substrate. If desired.

The substrate with the alignment marks and the TSVs may be formed as described above in various steps of FIG. 2, FIG. 5, and FIG. 12. The waveguide may be formed within a cladding layer, for example, by deposition of a first cladding sublayer. A trench is formed in the first cladding sublayer. The trench is then filled with appropriate material to form the waveguide. A second cladding sublayer is then formed over the first cladding sublayer to obtain the waveguide 520 within the cladding layer 510. Other structures may also be formed within the cladding layer, such as gratings, couplers, modulators/interferometers, ring resonators, photodetectors, etc.

The interposers and other structures described herein may be used in semiconductor devices that themselves might be used in various applications such as BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or image signal processors (ISP).

It is noted that certain process steps are not completely described each time in the discussion herein, and may be merely referred to with respect to their result. For example, a pattern/structure may be formed in a given layer by applying a photoresist layer, patterning the photoresist layer, developing the photoresist layer, and then etching, but the discussion below may refer only to patterning the given layer. For completeness, some of these various steps are described now.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl- 2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarizing may be performed to obtain a flat surface. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The methods and systems of the present disclosure include several different dielectric structures. Such dielectric structures can be made from any suitable combination of dielectric materials. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

Any electrically conductive material discussed herein may generally be any conductive metal. Examples of suitable metals may include copper, aluminum, nickel, chromium, gold, germanium, silver, titanium, tungsten, platinum, tantalum, ruthenium, cobalt, rhenium, palladium, or zirconium; composites like TiN, WN, or TaN; or alloys thereof like AlCu. The metal may be deposited, for example, via evaporation or sputtering, plating, chemical vapor deposition (CVD), physical vapor deposition (PVD), atomic layer deposition (ALD), or other suitable methods.

The methods and structures of the present disclosure have several advantages. The alignment marks can also be used as a measurement test line if desired. Alternatively, they may be dummy structures used only for alignment purposes. They will not be exposed on the back side of the interposer, and so bumps will not be formed thereon. They are not present in the wafer scribe lines, and so the dicing saw will not be affected.

The present disclosure thus relates in some embodiments to methods for forming an alignment mark on an interposer, or for forming an interposer with at least one alignment mark. A through-substrate via (TSV) trench and at least one alignment mark trench are formed in a chip area of a substrate. The TSV trench and the at least one alignment mark trench are then filled with a metal to form a filled TSV trench and the at least one alignment mark. The thickness of the substrate is reduced to form a through-substrate via (TSV) from the filled TSV trench.

Also disclosed in various embodiments are interposers with at least one alignment mark. An interposer substrate has a first/front side and a second/back side. At least one alignment mark is present on the first side of the substrate. At least one through-substrate via (TSV) extends through the substrate from the first side to the second side.

Also disclosed in various embodiments are methods for forming a semiconductor package containing an interposer. An interposer wafer substrate includes a plurality of chip areas. Each chip area contains at least one through-substrate via (TSV) trench and at least one alignment mark. One or more chips are bonded to a chip area. Underfill is applied to the wafer substrate. An encapsulation layer is then formed over the chip(s). The thickness of the interposer wafer substrate is reduced to expose the TSV trench and form a TSV. An electrical connector is formed upon the TSV. The interposer wafer substrate is then diced to form a semiconductor package from the chip area.

Also disclosed in various embodiments are semiconductor packages containing alignment marks upon the interposer as described above. Also disclosed in various embodiments herein are semiconductor devices including the interposers or the semiconductor packages described above, having alignment marks in the chip area.

Various embodiments disclosed herein also relate to methods for forming a substrate for silicon photonics. A through-substrate via (TSV) trench and at least one alignment mark trench are formed in a chip area of a substrate. The TSV trench and the at least one alignment mark trench are then filled with a metal to form a filled TSV trench and the at least one alignment mark. The thickness of the substrate is reduced to form a through-substrate via (TSV) from the filled TSV trench. A waveguide in a cladding layer is then formed upon the substrate. Also disclosed in various embodiments are the substrates for silicon photonics that thus result.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a through-substrate via (TSV) trench and at least one alignment mark trench in a chip area of a substrate;
filling the TSV trench and the at least one alignment mark trench with a metal to form a filled TSV trench and the at least one alignment mark; and
reducing a thickness of the substrate to form a through-substrate via (TSV) from the filled TSV trench.

2. The method of claim 1, wherein the TSV trench and the at least one alignment mark trench are formed by:
patterning a photoresist layer upon the substrate to include a TSV trench opening and at least one partial alignment mark trench opening; and
etching through the photoresist layer to form the TSV trench and the at least one alignment mark trench.

3. The method of claim 1, wherein the TSV trench and the at least one alignment mark trench are formed by:
patterning a photoresist layer upon the substrate to include at least one alignment trench opening;
etching through the photoresist layer to form the at least one alignment mark trench;
patterning a mask layer upon the substrate to include a TSV trench opening; and
etching through the mask layer to form the TSV trench.

4. The method of claim 1, further comprising:
etching through the mask layer to form the TSV trench.

5. The method of claim 4, further comprising:
forming a dielectric layer within the TSV trench.

6. The method of claim 1, further comprising:
forming a redistribution layer upon a front side of the substrate.

7. The method of claim 1, further comprising:
forming a bump on the TSV.

8. The method of claim 1, wherein the metal includes copper.

9. The method of claim 1, wherein a plan view of the at least one alignment mark has a circular, elliptical, polygonal, ring, or linear shape, or a combination thereof.

10. The method of claim 1, wherein in a plan view, the at least one alignment mark is formed from a combination of at least two lines that extend in different directions.

11. The method of claim 1, wherein the TSV has a front side plan surface area that is greater than a front side plan surface area of the at least one alignment mark.

12. The method of claim 1, wherein a plurality of alignment marks are formed at different corners of the chip area.

13. A method for forming an interposer with at least one alignment mark, comprising:
forming a through-substrate via (TSV) trench and at least one alignment mark trench in a chip area of a substrate;
filling the TSV trench and the at least one alignment mark trench with a metal to form a filled TSV trench and the at least one alignment mark in the chip area; and
reducing a thickness of the substrate to form a through-substrate via (TSV) from the filled TSV trench.

14. The method of claim 13, further comprising:
forming a redistribution layer upon a front side of the substrate.

15. The method of claim 13, further comprising:
forming a bump on the TSV.

16. The method of claim 13, further comprising:
dicing the substrate along wafer scribe lines around the chip area to separate the interposer.

17. An interposer, comprising:
a substrate having a first side and a second side opposite to the first side;
at least one alignment mark on the first side of the substrate;
at least one through-substrate via (TSV) extending through the substrate from the first side to the second side.

18. The interposer of claim 17, further comprising a redistribution layer upon the first side of the substrate.

19. The interposer of claim 17, further comprising a bump on each TSV on the second side of the substrate.

20. The interposer of claim 17, wherein the TSV has a first side plan surface area that is greater than a first side plan surface area of the at least one alignment mark.
